(19) United States
(12) Patent Application Publication
(10) Pub. No.: US 2025/0169130 A1
(43) Pub. Date: May 22, 2025

(54) INTEGRATED CIRCUIT STRUCTURES WITH DIFFERENT NANORIBBON THICKNESSES

(71) Applicant: Intel Corporation, Santa Clara, CA (US)

(72) Inventors: Tao Chu, Portland, OR (US); Minwoo Jang, Portland, OR (US); Yanbin Luo, Portland, OR (US); Paul Packan, Hillsboro, OR (US); Guowei Xu, Portland, OR (US); Chiao-Ti Huang, Portland, OR (US); Robin Chao, Portland, OR (US); Feng Zhang, Hillsboro, OR (US); Ting-Hsiang Hung, Beaverton, OR (US); Chia-Ching Lin, Portland, OR (US); Yang Zhang, Rio Rancho, NM (US); Kan Zhang, HILLSBORO, OR (US); Chung-Hsun Lin, Portland, OR (US); Anand S. Murthy, Portland, OR (US)

(73) Assignee: Intel Corporation, Santa Clara, CA (US)

(21) Appl. No.: 18/515,626

(22) Filed: Nov. 21, 2023

(51) Int. Cl. H01L 29/06; H01L 21/8234; H01L 27/088; H01L 29/423; H01L 29/66

(52) U.S. Cl. CPC H10D 62/118; H10D 30/6735; H10D 64/017; H10D 84/0128; H10D 84/038; H10D 84/83

(57) ABSTRACT

Fabrication methods for integrated circuit (IC) structures and devices with different nanoribbon thicknesses are disclosed. In one example, an IC structure includes a stack of nanoribbons stacked above one another over the support, including a first nanoribbon with a first channel region and a second nanoribbon with a second channel region, where the first channel region has a first thickness and the second channel region has a second thickness, and where the first thickness of the first channel region is different (e.g., greater) than the second thickness of the second channel region.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 illustrates an example of an IC structure with different nanoribbon thicknesses.

FIG. 2 provides a perspective view of an example nanoribbon-based field-effect transistor (FET), according to some embodiments of the present disclosure.

FIG. 3 is a flow diagram of an example method of fabricating an IC structure with a stack of nanoribbons with different thicknesses, in accordance with some embodiments.

FIGS. 4A-4J provide cross-sectional side views at various stages in the fabrication of an example IC structure according to the method of FIG. 3, in accordance with some embodiments.

FIG. 5 is a top view of a wafer and dies that may include any of the IC structures disclosed herein, in accordance with any of the embodiments disclosed herein.

FIG. 6 is a side, cross-sectional view of an IC device that may include any of the IC structures disclosed herein, in accordance with any of the embodiments disclosed herein.

FIG. 7 is a side, cross-sectional view of an IC package that may include any of the IC structures disclosed herein, in accordance with various embodiments.

FIG. 8 is a side, cross-sectional view of an IC device assembly that may include any of the IC structures disclosed herein, in accordance with any of the embodiments disclosed herein.

FIG. 9 is a block diagram of an example electrical device that may include any of the IC structures disclosed herein, in accordance with any of the embodiments disclosed herein.

### DETAILED DESCRIPTION

Integrated circuit structures and devices having different nanoribbon thicknesses and methods for fabricating such IC structures are described herein. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

As advances in semiconductor fabrication enable smaller transistor sizes, effects known as short channel effects can have an increasingly significant impact on the performance and functionality of transistors. As the name suggests, short channel effects are typically greater as the length of the channel becomes shorter. Short channel effects can result in issues such as increased leakage current, drain-induced barrier lowering, velocity saturation, reduction in threshold voltage, and unintentional subthreshold conduction through the transistor, all of which can negatively impact performance and/or result in failure of the transistors.

In some examples, nanoribbon transistors may have non-ideal features, such as a tapered source/drain region that has a narrower width at its bottom than at its top. In one such example, the tapered shape of source/drain regions in nanoribbon transistors can result in suboptimal performance due to different short channel effects in the channel regions in different nanoribbons of a transistor.

Forming nanoribbon transistors with different nanoribbon thicknesses can enable optimization of short channel effects and improved performance. For example, IC structures including nanoribbons having different thicknesses can enable more uniform short channel effects between different nanoribbons of a stack, which can simplify mitigating and/or accounting for short channel effects. IC structures as described herein, in particular IC structures including a stack of nanoribbons having different thicknesses, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures that include different nanoribbons thicknesses as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

IC structures with a stack of nanoribbons having different thicknesses may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surfaces. A confinement surface refers to a particular orientation of the channel surface that is confined by the gate field. Non-planar transistors potentially improve performance relative to transistors having a planar architecture, such as single-gate transistors.

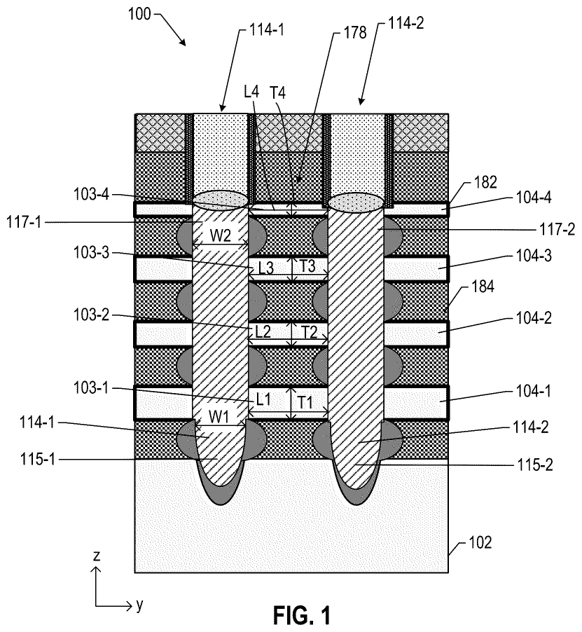

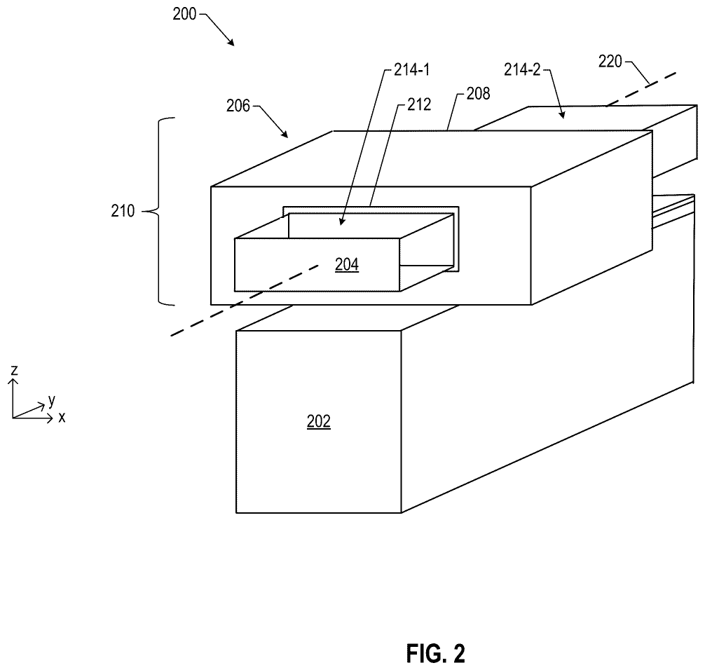

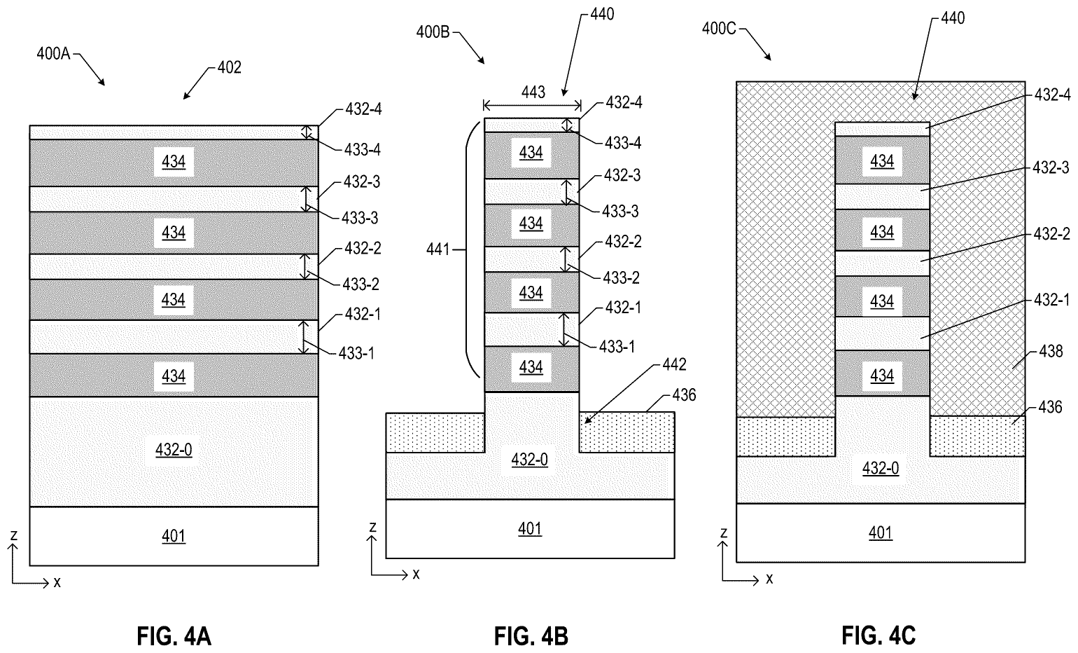

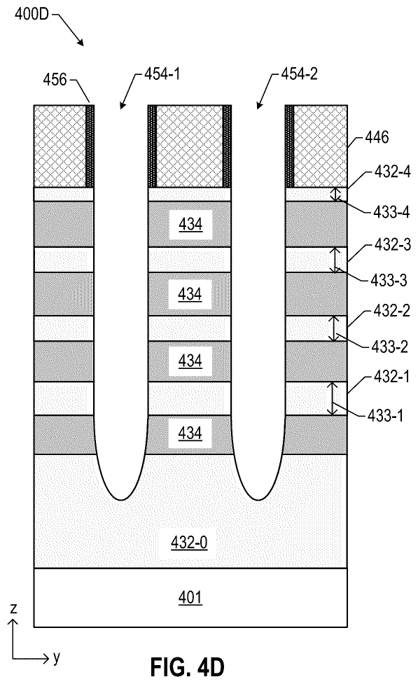

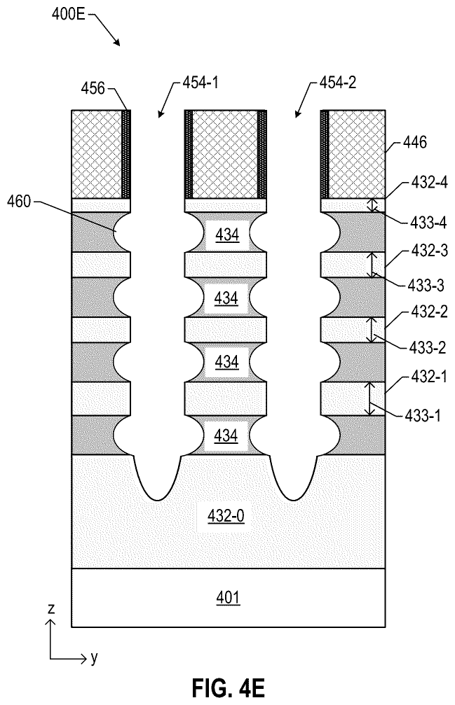

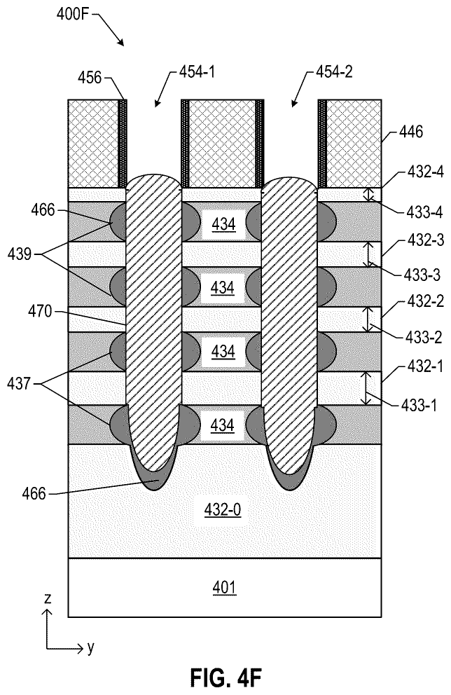

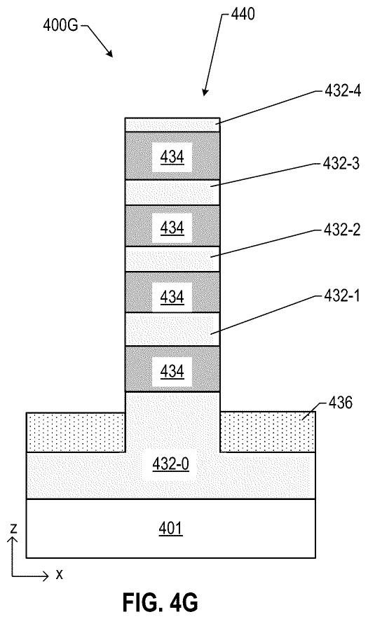

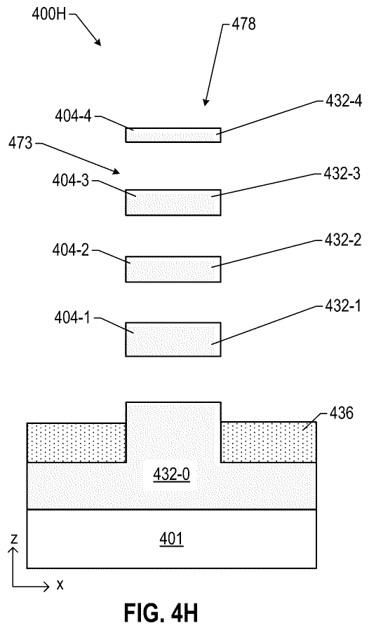

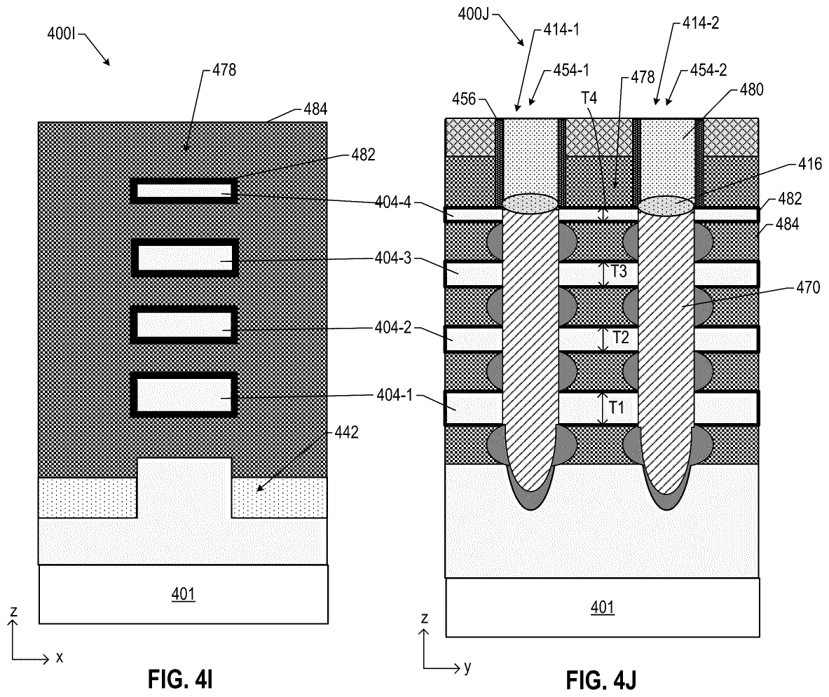

Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Therefore, some IC structures illustrated herein show nanoribbon transistors as an example (e.g., IC structures shown in FIG. 1, FIG. 2, FIG. 4I, and FIG. 4J).

As used herein, the term “nanoribbon” refers to an elongated structure of a semiconductor material having a longitudinal axis parallel to a support structure (e.g., a substrate, a die, a chip, or a wafer) over which such a structure is built. Typically, a length of a such a structure (i.e., a dimension measured along the longitudinal axis, shown in the present drawings to be along the y-axis of an example x-y-z coordinate system shown in FIG. 2) is greater than each of a width (i.e., a dimension measured along the x-axis of the coordinate system) and a thickness/height (i.e., a dimension measured along the z-axis of the coordinate system). In some settings, the terms “nanoribbon” or “nanosheet” have been used to describe elongated semiconductor structures that have a rectangular transverse cross-section (i.e., a cross-section in a plane perpendicular to the longitudinal axis of the structure), while the term “nanowire” has been used to describe similar elongated structures but with circular transverse cross-sections. In the present disclosure, the term “nanoribbon” is used to refer to all such nanowires, nanoribbons, and nanosheets, as well as elongated semiconductor structures with a longitudinal axis parallel to the support structures and with having transverse cross-sections of any geometry (e.g., transverse cross-sections in the shape of an oval or a polygon with rounded corners). A transistor may then be described as a “nanoribbon transistor” if the channel of the transistor is a portion of a nanoribbon, i.e., a portion around which a gate stack of a transistor may wrap around. The semiconductor material in the portion of the nanoribbon that forms a channel of a transistor may be referred to as a “channel material,” with source and drain regions of a transistor provided on either side of the channel material.

FIG. 1 illustrates an example of an IC structure 100 with different nanoribbon thicknesses. The IC structure 100 includes a support structure 102 and a stack 178 of nanoribbons (e.g., two or more nanoribbons) stacked above one another over the support structure 102. The support structure 102 can be, for example, a substrate, a die, a chip, a wafer or other support structure, and may be referred to herein as a “support.” In the illustrated example, the nanoribbons 104-1-104-4 of the stack 178 include a semiconductor material in which channel regions 103-1-103-4 of a transistor are formed. For example, the IC structure 100 includes a first channel region 103-1 in a first nanoribbon 104-1, a second channel region 103-2 in a second nanoribbon 104-2, a third channel region 103-3 in a third nanoribbon 104-3, and a fourth channel region 103-4 in a fourth nanoribbon 104-4.

The IC structure 100 of FIG. 1 includes a gate insulator material 182 that may wrap around the channel regions 103-1-103-4 of the nanoribbons 104-1-104-4 of the stack 178, as well as a gate electrode material 184. In the illustrated example, the gate electrode material 184 is a continuous gate electrode material that encloses the channel regions 103-1-103-4 of a transistor. The gate insulator material 182 can include a high-k dielectric or other suitable insulator material. The gate electrode material 184 can include a conductive material in accordance with examples described below. In some embodiments, the gate insulator material 182 may be absent in the IC structure 100.

The channel regions 103-1-103-4 are between source and drain regions (“S/D regions”) 114-1 and 114-2 (referred to herein as simply “S/D regions 114”), where one of the regions 114-1 and 114-2 is a source region and the other of the regions 114-1 and 114-2 is a drain region. In one example, the S/D regions are regions including a doped semiconductor material, which act as source and drain regions for a transistor. The S/D regions 114-1 and 114-2 may have a tapered shape in which portions 115-1, 115-2 of the regions 114-1, 114-2 (e.g., the bottom of the S/D regions) have a smaller width than other portion 117-1, 117-2 of the regions 114-1, 114-2 (e.g., the top of the S/D regions). For example, the region 114-1 includes a first portion 115-1 having a first width W1 and a second portion 117-1 having a second width W2 that is greater than W1, where the width of the S/D regions is in a plane substantially parallel to the support 102.

Due to the tapered shape of the S/D regions 114-1, 114-2, a channel region in a nanoribbon at the bottom may have a length that is greater than a channel region in a nanoribbon at the top of the stack. For example, the channel regions closer to the narrow portions 115-1, 115-2 of the S/D regions 114-1, 114-2 may have a larger length than the channel regions closer to the wider portions 117-1, 117-2 of the S/D regions 114-1, 114-2. In the example illustrated in FIG. 1, the channel region 103-1 has a length L1, the channel region 103-2 has a length L2, the channel region 103-3 has a length L3, and the channel region 103-4 has a length L4, where the length of a channel region is a dimension of the channel region (e.g., between adjacent S/D regions) in a plane substantially parallel to the support 102 (e.g., in the y-x plane, where the x-axis is going into and coming out of the page in FIG. 1). In one example, the channel region 103-1 that is closer to the first portion 115-1 of the region 114-1 has a larger length than the channel region 103-4 that is closer to the second portion 117-1 (e.g., L1>L4). Thus, the length of the channel regions 103-1-103-4 in nanoribbons 104-1-104-4 at different positions in the stack 178 can be different due to, e.g., the shape and/or dimensions of the S/D regions.

In the example illustrated in FIG. 1, the channel regions in two or more of the nanoribbons 104-1-104-4 of the stack 178 have different thicknesses, where the thickness of a nanoribbon is a dimension of the nanoribbon in a plane substantially perpendicular to the support 102 (e.g., along the z-axis as shown in FIG. 1). For example, the channel region 103-1 has a first thickness T1, the channel region 103-2 has a second thickness T2, the channel region 103-3 has a third thickness T3, and the channel region 103-4 has a fourth thickness T4. In the example illustrated in FIG. 1, the first thickness T1 is greater than the second thickness T2, the second thickness T2 is substantially the same as or greater than the third thickness T3, and the third thickness T3 is greater than the fourth thickness T4. According to some examples, the thickness of a nanoribbon may be in a range of about 3-10 nanometers, 3.5-7 nanometers, or 3-6 nanometers. Other nanoribbon thicknesses are possible (e.g., greater than 10 nanometers).

In one example, the difference in thickness of two vertically adjacent nanoribbons with different thicknesses is in a range of about 0.2-1 nanometers, 0.3-0.7 nanometers, or 0.3-0.5 nanometers, where vertically adjacent nanoribbons are nanoribbons that are stacked over one another over the support 102. For example, the difference in thickness between the nanoribbon 104-1 and the nanoribbon 104-2 may be in the range of 0.2-1 nanometers. In one such example, if the nanoribbon 104-1 has the thickness T1, the nanoribbon 104-2 may have the thickness in a range of T1 minus 0.2 nanometer (T1−0.2 nm) to T1 minus 1 nanometer (T1−1 nm). However, other ranges are possible (e.g., the difference in thickness between two adjacent nanoribbons in a stack may include values that are less than or greater than the examples provided). In one example, the difference in thickness of two vertically adjacent nanoribbons is in a range of about 5-20% of the thickness one of the nanoribbons, about 5-15% of the thickness of one of the nanoribbons, or about 6-11% of the thickness of one of the nanoribbons. Also note that these exemplary ranges are for two adjacent nanoribbons with different thicknesses; however, in some examples, the stack may include two or more adjacent nanoribbons with the same thickness. For example, the nanoribbons 104-1 and 104-2 may have a different thickness from one another, but two other adjacent nanoribbons (e.g., the nanoribbons 104-2 and 104-3) may have about the same thickness, in accordance with some embodiments.

The thickness of the nanoribbon (and therefore the thickness of the channel region in the nanoribbon) may depend on the location of the nanoribbon in the stack. For example, the bottom nanoribbon(s) in the stack may be thicker than the top or upper nanoribbon(s) in the stack. For example, referring to FIG. 1, a channel region 103-1 having a larger thickness T1 (e.g., relative to another channel region) is in the bottom nanoribbon 104-1 of the stack 178, and a channel region having a smaller thickness T4 is in a top nanoribbon 104-4 of the stack 178. In this example, the bottom nanoribbon is closer to the support 102, closer to the tapered portion of the adjacent S/D regions, and/or closer to a subfin under the stack of nanoribbons than a channel region having a smaller thickness. Similarly, in one example, a channel region having a smaller thickness (e.g., relative to another channel region) may be closer to a source contact or a drain contact (e.g., one or more of S/D contacts 114-1, 114-2) than a channel region having a larger thickness. However, in other examples, the location of thicker or thinner nanoribbons in the stack relative to other elements of the IC structure may be different (e.g., in an IC structure with a backside contact, the location of the nanoribbons relative to the S/D contacts may be different).

As mentioned above, channel regions in different nanoribbons may have different lengths. In one example, the nanoribbons are formed with different thicknesses based on the expected lengths of the channel regions in those nanoribbons. For example, a channel region that is longer (e.g., relative to another channel region in another nanoribbon of the stack) is formed in a thicker nanoribbon than the shorter channel region. Thus, in one such example, a channel region with a larger length (relative to another channel region of the transistor) has a larger thickness than a channel region with a shorter length. For example, referring to FIG. 1, the IC structure 100 includes a channel region 103-1 having the length L1 that is greater than the length L4 of the channel region 103-4. The channel region 103-1 having the larger length L1 also has a thickness T1 that is greater than a thickness T4 of the shorter channel region 103-4. In one example, the ratio of the channel thickness (e.g., nanoribbon thickness in the channel region) divided by channel length is substantially the same for channel regions in nanoribbons in a stack. For example, a first ratio of T1/L1 may be substantially the same as T2/L2, which is substantially the same as T3/L3, which is substantially the same as T4/L4. However, in some embodiments, one or more of the channel regions may not have substantially the same ratio of channel thickness over channel length.

Thus, FIG. 1 illustrates an example of an IC structure that includes a stack of nanoribbons in which at least one of the nanoribbons has a different thickness than the other nanoribbons, and therefore at least one of the channel regions in those nanoribbons has a different thickness than the other channel regions. In various implementations, each of the channel regions can have different thicknesses or two or more of the channel regions may have the same thickness. Thus, in one example, the stack of nanoribbons includes at least a first nanoribbon with a first channel region (e.g., channel region 103-1) and a second nanoribbon with a second channel region (e.g., 103-2), where the first channel region has a first thickness (e.g., T1), the second channel region has a second thickness (e.g., T2), and where the first thickness is different than the second thickness (e.g., T1 is thicker than T2). In some examples, a third nanoribbon with a third channel region having a third thickness (e.g., the channel region 103-3 with the thickness T3) may also be different than the first and second thicknesses (e.g., T1 and T2 may be thicker than T3), and so forth.

Although FIG. 1 illustrates an example with four nanoribbons 104-1-104-4, other IC structures can include a different number of nanoribbons with different thicknesses (e.g., two, three, or more than four nanoribbons). The differentiated nanoribbon thickness can enable more uniform short channel effects in all the channel regions of the transistor.

FIG. 2 provides a perspective view of an example IC structure 200 with a nanoribbon transistor 210, according to some embodiments of the present disclosure. As shown in FIG. 2, the IC structure 200 includes a semiconductor material formed as a nanoribbon 204 extending substantially parallel to a support 202. The transistor 210 may be formed on the basis of the nanoribbon 204 by having a gate stack 206 wrap around at least a portion of the nanoribbon referred to as a “channel portion” and by having source and drain regions, shown in FIG. 2 as a first S/D region 214-1 and a second S/D region 214-2 (referred to herein as simply “S/D regions 214), on either side of the gate stack 206. One of the S/D regions 214 is a source region and the other one is a drain region. However, because, as is common in the field of FETs, designations of source and drain are often interchangeable, they are simply referred to herein as a first S/D region 214-1 and a second S/D region 214-2.

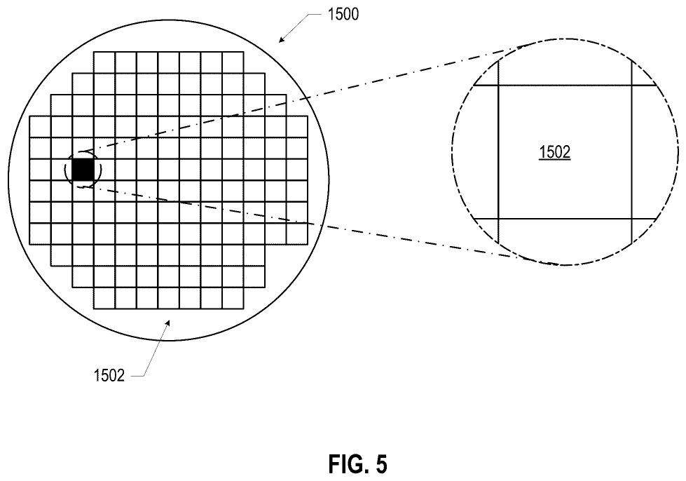

Implementations of the present disclosure may be formed or carried out on any suitable support 202, such as a substrate, a die, a wafer, or a chip. The support 202 may, e.g., be the wafer 1500 of FIG. 5, discussed below, and may be, or be included in, a die, e.g., the singulated die 1502 of FIG. 5, discussed below. The support 202 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 202 may be a printed circuit board (PCB) substrate, a package substrate, an interposer, a wafer, or a die.

Although a few examples of materials from which the support 202 may be formed are described here, any material that may serve as a foundation upon which an IC structure including a self-insulated via as described herein may be built falls within the spirit and scope of the present disclosure. Although only one nanoribbon 204 is shown in FIG. 2, the IC structure 200 may include a stack of such nanoribbons where a plurality of nanoribbons 204 are stacked above one another. For example, FIGS. 1, FIG. 4I, and FIG. 4J show IC structures that may be examples of the IC structure 200. In some embodiments, a portion of the support 202 right below the lowest nanoribbon 204 of the stack may be shaped as a subfin extending away from a base, as is known in the field of nanoribbon transistors.

The nanoribbon 204 may take the form of a nanowire or nanoribbon, for example. In some embodiments, an area of a transversal cross-section of the nanoribbon 204 (i.e., an area in the x-z plane of an x-y-z coordinate system shown in FIG. 2, perpendicular to a longitudinal axis 220 of the nanoribbon 204) may be between about 25 and 10000 square nanometers, including all values and ranges therein (e.g., between about 25 and 1000 square nanometers, or between about 25 and 500 square nanometers). In some embodiments, a width of the nanoribbon 204 (i.e., a dimension measured in a plane parallel to the support 202 and in a direction perpendicular to the longitudinal axis 220 of the nanoribbon 204, e.g., along the x-axis of the coordinate system) may be at least about 3 times larger than a height or thickness of the nanoribbon 204 (i.e., a dimension measured in a plane perpendicular to the support 202, e.g., along the z-axis of the coordinate system), including all values and ranges therein, e.g., at least about 4 times larger, or at least about 5 times larger. Although the nanoribbon 204 illustrated in FIG. 2 is shown as having a rectangular cross-section, the nanoribbon 204 may instead have a cross-section that is rounded at corners or otherwise irregularly shaped, and the gate stack 206 may conform to the shape of the nanoribbon 204. The term “face” of a nanoribbon may refer to the side of the nanoribbon 204 that is larger than the side perpendicular to it (when measured in a plane substantially perpendicular to the longitudinal axis 220 of the nanoribbon 204), the latter side being referred to as a “sidewall” of a nanoribbon.

In various embodiments, the semiconductor material of the nanoribbon 204 may be composed of semiconductor material systems including, for example, N-type or P-type materials systems. In some embodiments, the nanoribbon 204 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 204 may include a combination of semiconductor materials. In some embodiments, the nanoribbon 204 may include a monocrystalline semiconductor, such as silicon (Si) or germanium (Ge). In some embodiments, the nanoribbon 204 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 210 is an N-type metal-oxide-semiconductor (NMOS) transistor), the channel material of the nanoribbon 204 may include a III-V material having a relatively high electron mobility, such as, but not limited to InGaAs, InP, InSb, and InAs. For some such embodiments, the channel material of the nanoribbon 204 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 210 is a P-type metal-oxide-semiconductor (PMOS) transistor), the channel material of the nanoribbon 204 may advantageously be a group IV material having a high hole mobility, such as, but not limited to Ge or a Ge-rich SiGe alloy. For some example embodiments, the channel material of the nanoribbon 204 may have a Ge content between 0.6 and 0.9, and advantageously may be at least 0.7.

In some embodiments, the channel material of the nanoribbon 204 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 204 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 204 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 206 including a gate electrode material 208 and, optionally, a gate insulator material 212, may wrap entirely or almost entirely around a portion of the nanoribbon 204 as shown in FIG. 2, with the active region (channel region) of the channel material of the transistor 210 corresponding to the portion of the nanoribbon 204 wrapped by the gate stack 206. As shown in FIG. 2, the gate insulator material 212 may wrap around a transversal portion of the nanoribbon 204 and the gate electrode material 208 may wrap around the gate insulator material 212.

The gate electrode material 208 may include one or more gate electrode materials, where the choice of the gate electrode materials may depend on whether the transistor 210 is a PMOS transistor or an NMOS transistor. For a PMOS transistor, gate electrode materials that may be used in different portions of the gate electrode material 208 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 208 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 208 may include a stack of a plurality of gate electrode materials, where zero or more materials of the stack are workfunction (WF) materials and at least one material of the stack is a fill metal layer. Further materials/layers may be included next to the gate electrode material 208 for other purposes, such as to act as a diffusion barrier layer or/and an adhesion layer.

In some embodiments, the gate insulator material 212 may include one or more high-k dielectrics including any of the materials discussed herein with reference to the insulator material that may surround portions of the transistor 210. In some embodiments, an annealing process may be carried out on the gate insulator material 212 during fabrication of the transistor 210 to improve the quality of the gate insulator material 212. The gate insulator material 212 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 206 may be surrounded by a gate spacer, not shown in FIG. 2. Such a gate spacer would be configured to provide separation between the gate stack 206 and S/D contacts of the transistor 210 and could be made of a low-k dielectric material, some examples of which have been provided above.

Turning to the S/D regions 214 of the transistor 210, in some embodiments, the S/D regions may be highly doped, e.g., with dopant concentrations of about 10²¹ cm⁻³, in order to advantageously form Ohmic contacts with the respective S/D contacts (not shown in FIG. 2), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 214-1 and the second S/D region 214-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 214.

The S/D regions 214 of the transistor 210 may generally be formed using either an implantation/diffusion process or an etching/deposition process. In the former process, dopants such as boron, aluminum, antimony, phosphorous, or arsenic may be ion-implanted into the nanoribbon 204 to form the source and drain regions. An annealing process that activates the dopants and causes them to diffuse further into the nanoribbon 204 may follow the ion implantation process. In the latter process, portions of the nanoribbon 204 may first be etched to form recesses at the locations of the future S/D regions 214. An epitaxial deposition process may then be carried out to fill the recesses with material that is used to fabricate the S/D regions 214. In some implementations, the S/D regions 214 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 214 may be formed using one or more alternate semiconductor materials such as germanium or a group III-V material or alloy. And in further embodiments, one or more layers of metal and/or metal alloys may be used to form the S/D regions 214. In some embodiments, a distance between the first and second S/D regions 214 (i.e., a dimension measured along the longitudinal axis 220 of the nanoribbon 204) may be between about 5 and 40 nanometers, including all values and ranges therein (e.g., between about 22 and 35 nanometers, or between about 20 and 30 nanometers).

The IC structure 200 shown in FIG. 2, as well as IC structures shown in other drawings of the present disclosure, is intended to show relative arrangements of some of the components therein, and the IC structure 200, or portions thereof, may include other components that are not illustrated (e.g., electrical contacts to the S/D regions 214 of the transistor 210, additional layers such as a spacer layer around the gate electrode of the transistor 210, etc.). For example, although not specifically illustrated in FIG. 2, a dielectric spacer may be provided between a first S/D contact (which may also be referred to as a “first S/D electrode”) coupled to a first S/D region 214-1 of the transistor 210 and the gate stack 206 as well as between a second S/D contact (which may also be referred to as a “second S/D electrode”) coupled to a second S/D region 214-2 of the transistor 210 and the gate stack 206 in order to provide electrical isolation between the source, gate, and drain electrodes. In another example, although not specifically illustrated in FIG. 2, at least portions of the transistor 210 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 210 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

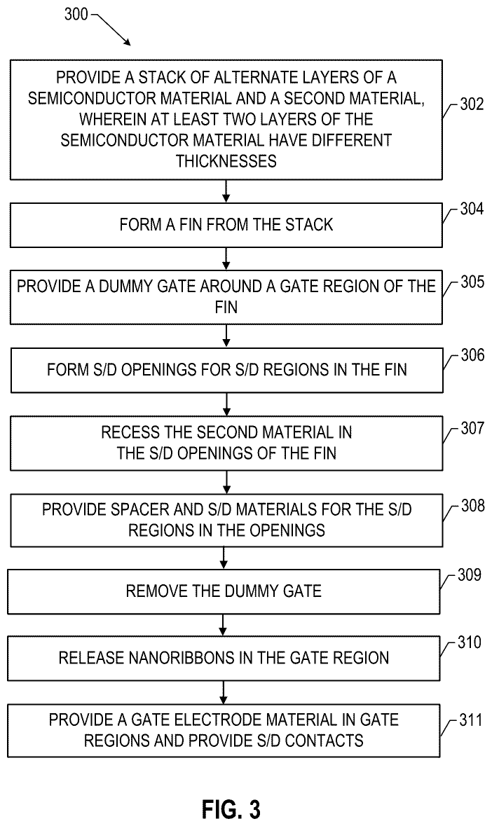

FIG. 3 is a flow diagram of an example method for fabricating an IC structure that includes a stack of nanoribbons with different thicknesses, in accordance with some embodiments. FIGS. 4A-4J provide cross-sectional side views at various stages in the fabrication of an example IC structure according to the method of FIG. 3, in accordance with some embodiments.

Although the operations of the method of FIG. 3 are illustrated once each and in a particular order, the operations may be performed in any suitable order and repeated as desired. For example, one or more operations may be performed in parallel to fabricate multiple IC structures with a stack of nanoribbons having different thicknesses substantially simultaneously. In another example, the operations may be performed in a different order to reflect the structure of an IC device in which an IC structure with a stack of nanoribbon having different thicknesses will be implemented.

In addition, the example fabricating method of FIG. 3 may include other operations not specifically shown in FIG. 3, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 3 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 3, the method 300 begins with a process 302 of providing a stack of alternate layers of a semiconductor material and a second material (e.g., a second semiconductor material), where at least two layers of the semiconductor material have different thicknesses. An IC structure 400A of FIG. 4A illustrates an example result of the process 302. The IC structure 400A includes a support 401 and alternating layers of a semiconductor material (e.g., layers 432-1-432-4, referred to herein as “layers 432” or “semiconductor material 432”) and layers of a second material 434. While FIG. 4A illustrates five layers of the semiconductor material 432 (labeled as layers 432-0 through 432-4) and four layers of the second material 434 in a stack 402, in other embodiments, any other number of layers may be used as long as they are alternating and include at least three layers of the semiconductor material 432 and at least two layers of the second material 434. The upper layers of the semiconductor material 432 will later be formed into nanoribbons stacked above one another, as shown in FIGS. 4I and 4J, discussed below. Thus, although a particular number of nanoribbons formed of the upper layers of the semiconductor material 432 is depicted in FIGS. 4I and 4J (namely, four nanoribbons) and subsequent drawings, embodiments of the present disclosure include IC structures having more or fewer stacked nanoribbons than depicted. As shown in FIG. 4A, in some embodiments, the alternation of layers of the semiconductor material 432 and the second material 434 may begin after a bottom layer of the semiconductor material 432 (i.e., the layer 432-0) is provided over the support 401. In one such example, the bottom layer 432-0 may later form a subfin under the stack of nanoribbons. Although the thickness of the bottom layer 432-0 of the semiconductor material is depicted as being greater than the subsequent layers 432-1-432-4 of the semiconductor material that are formed into nanoribbons via further processing, in other examples, the bottom layer 432-0 may have a substantially same thickness as another layer of the semiconductor material 432.

The semiconductor material 432 may be any of the semiconductor/channel materials described above with reference to the nanoribbons 104 of FIG. 1 and the nanoribbon 204 of FIG. 2. The second material 434 may be any suitable material that is etch-selective with respect to the semiconductor material 432 so that, in a later process, the second material 434 may be etched away to form nanoribbons of the semiconductor material 432. As known in the art, two materials are said to be “etch-selective” (or said to have “sufficient etch selectivity”) with respect to one another when etchants used to etch one material do not substantially etch the other, enabling selective etching of one material but not the other. For example, in some embodiments, the semiconductor material 432 may be silicon while the second material 434 may be a second semiconductor material such as silicon germanium. In another example, the semiconductor material 432 may be silicon germanium, while the second material 434 may be silicon. In other examples, the second material may be made of a non-semiconductor material, e.g., of an insulator material, as long as this material is sufficiently etch-selective with respect to the semiconductor material 432.

Thus, the material 434 may be any suitable sacrificial material that is etch-selective with respect to the semiconductor material 432. Selecting the material 434 to be a semiconductor material may be particularly advantageous because it may improve quality of the semiconductor material 432 if the semiconductor material 432 is epitaxially grown on the material 434. In some embodiments, the process 302 may include epitaxially growing layers of the semiconductor material 432 and the second material 434 (e.g., a second semiconductor material) in an alternating manner. In other embodiments, alternate layers of the semiconductor material 432 and the second material 434 may be provided in the process 302 using other techniques, such as layer transfer or thin-film deposition. Although FIG. 4A illustrates the same semiconductor material 432 in various layers of the IC structure 400A, in general, material compositions of a semiconductor material from which nanoribbons will later be formed in different layers of the IC structure 400A may be different. For example, the semiconductor material 432 of one layer of the IC structure 400A may be silicon while the semiconductor material 432 of another layer of the IC structure 400A may be a III-N semiconductor material such as GaN.

As mentioned above, the layers 432-1-432-4 in the stack 402 are to be later formed into a stack of nanoribbons, where channel regions of a transistor are formed in portions of the nanoribbons. To form a stack of nanoribbons in which at least one nanoribbon has a different thickness than the other nanoribbons in the stack, the process 302 involves providing layers of semiconductor material having different thicknesses. Specifically, in FIG. 4A, the layer 432-1 has a thickness 433-1, the layer 432-2 has a thickness 433-2, the layer 432-3 has a thickness 433-3, and the layer 432-4 has a thickness 433-4. In this example illustrated in FIG. 4A, the thickness 433-1 is different than (e.g., greater than) the thickness 433-2 and the thickness 433-2 is different than (e.g., greater than) the thickness 433-4. In one example, each of the layers of semiconductor material to be formed into nanoribbons has a different thickness. In another example, two or more of the layers of the semiconductor material may have the same thickness (e.g., FIG. 1 depicts the thickness 433-2 of the layer 432-2 as being about the same as the thickness 433-3 of the layer 432-3). In other examples, other layers of the semiconductor material may also or alternatively have the same thickness (e.g., the thickness 433-4 of the layer 432-4 may be about the same as the thickness 433-3 of the layer 432-3).

Turning again to FIG. 3, the method 300 continues with a process 304 of forming a fin from the stack. An IC structure 400B of FIG. 4B illustrates an example result of the process 304. The IC structure 400B illustrates that the stack 402 of alternating layers of the semiconductor material 432 and the second material 434 has been patterned into a fin 440. The fin 440 may include an active portion 441 and a subfin portion 442. The active portion 441 may be a portion of the fin 440 from which later the respective nanoribbons will be formed, while the subfin portion 442 is a portion of the fin 440 that has sidewalls at least partially enclosed with an insulator material 436, e.g., as shown in FIG. 4B. The insulator material 436 may include any of insulator material typically used as a “shallow trench insulator” (STI) in fin-based or nanoribbon-based transistors, e.g., any suitable low-k dielectric material or other suitable insulator material.

Thus, the fin 440 may be shaped as a structure that extends away from the support 401 and may include a subfin 442 at the bottom, the subfin 442 being a portion of the fin 440 that is at least partially enclosed by an insulator material 436. In some embodiments, the subfin 442 may include the bottom layer 432-0 of the semiconductor material deposited at process 302, as well as an upper portion of the support 401, as is shown in FIG. 4B and the subsequent drawings. However, in other embodiments, the subfin 442 may include only the semiconductor material 432 and not any portions of the support 401 (not shown in the present drawings). In some embodiments, semiconductor material 432 of the subfin 442 and/or the support 401 may be removed and/or replaced with one or more other materials in subsequent processes.

In some embodiments, the fin 440 may have a width 443 (i.e., a dimension of the fin 440 measured along the x-axis of the example coordinate system shown in FIG. 4B). The width 443 may be that of the width of the nanoribbons subsequently formed (e.g., the nanoribbon 204 of FIG. 2 described above). The fin 440 may further have a length (i.e., a dimension of the fin 440 measured along the y-axis of the example coordinate system shown in FIG. 4B, where the y-axis is going into and coming out of the page) suitable to account for the length of the future nanoribbons (e.g., as described above with reference to the length of the nanoribbon 204 of FIG. 2).

In various embodiments, any suitable patterning techniques may be used in the process 304 to form the fin 440, such as, but not limited to, photolithographic or electron-beam (e-beam) patterning, possibly in conjunction with a suitable etching technique, e.g., a dry etch, such as e.g., RF reactive ion etch (RIE) or inductively coupled plasma (ICP) RIE. In some embodiments, the etch performed in the process 304 may include an anisotropic etch, using etchants in a form of e.g., chemically active ionized gas (i.e., plasma) using e.g., bromine (Br) and chloride (CI) based chemistries. In some embodiments, during the etch of the process 304, the IC structure may be heated to elevated temperatures, e.g., to temperatures between about room temperature and 200 degrees Celsius, including all values and ranges therein, to promote that byproducts of the etch are made sufficiently volatile to be removed from the surface.

Referring to FIG. 3, the method 300 continues with a process 305 with providing a dummy gate around a gate region of the fin. An IC structure 400C of FIG. 4C illustrates an example result of the process 305. The IC structure 400C illustrates the fin 440 over the support 401 and a material 446, which may be referred to as a dummy gate or replacement gate. In one example, the material 446 may be any suitable material such as polysilicon.

The method 300 continues with a process 306 of forming source/drain (S/D) openings for S/D regions in the fin. An IC structure 400D of FIG. 4D illustrates an example result of the process 306. FIG. 4D illustrates the IC structure after forming S/D openings from the perspective of the y-z plane in a cross-section along the fin 440. As shown in FIG. 4D, the process 306 involves forming a first opening 454-1 and a second opening 454-2 (together referred to as “openings 454”) in the fin 440. Any suitable etching technique may be used to form the openings 454, such as the techniques described above with respect to the process 304. In some embodiments, portions of the openings 454 surrounded by the dummy gate 446 may be lined with a liner 456, which may include a plurality of different liners even though it is shown in FIG. 4D as a single liner 456. The liner 456 may include one or more of spacer materials, diffusion barrier materials, adhesion materials, etc., as known in the art for forming contacts to various components of IC structures.

The method 300 continues with the process 307 of recessing the second material in the S/D openings of the fin. An IC structure 400E of FIG. 4E illustrates an example result of the process 307. As can be seen in FIG. 4E, as a result of recessing the second material 434, so-called “dimples” 460 may be formed in the sidewalls of the S/D openings 454 in the fin 440, where the dimples 460 are areas in which the second material 434 was recessed away from the original sidewalls of the openings 454 (i.e., recessed laterally). Any suitable etching technique may be used in the process 307 to recess the second material 434 in the S/D openings 454, such as any suitable wet etching technique using etchants that can etch the second material 434 without substantially etching other material of the IC structure 400E. The dimples 460 may have any suitable geometry and dimensions so that, when filled with an insulator material in a later process, the dimples 460 may provide electrical insulation between the material of the S/D regions that will be within the S/D openings 454 formed in the fin 440 and the gate electrode material that will be present between the nanoribbons of the semiconductor material 432 formed from the fin 440. For example, a depth of the dimples 460, which is a dimension that is measured along the y-axis of the example coordinate system shown, may be between about 1 and 20 nanometers, e.g., between about 2 and 10 nanometers, or between about 3 and 7 nanometers.

Referring again to FIG. 3, the method 300 continues with the process 308 of providing spacer and S/D material for the S/D regions in the openings. An IC structure 400F of FIG. 4F illustrates an example result of the process 308. As shown in FIG. 4F, the dimples 460 may be filled with a spacer material 466. Furthermore, the spacer material 466 may also line bottoms of the openings 454. In one such example, the spacer material 466 lines the subfin portion of the fin 440. Remaining portions of the openings 454 may be filled with respective S/D materials, shown as a S/D material 470 in the openings 454. The spacer material 466 may include any suitable insulator material, while the S/D materials 470 may include any materials for forming S/D regions (e.g., such as the S/D regions 214 of FIG. 2) of nanoribbon-based transistors. Techniques for filling S/D openings with a spacer material and S/D material during fabrication of nanoribbon-based transistors are known in the art and, therefore, are not described here in detail. In one example, as a result of the different thicknesses of the layers 432-1-432-4 of semiconductor material (e.g., the different thicknesses 433-1 and 433-3), the spacer material 466 in adjacent recessed regions proximate to the bottom of the S/D regions are separated by a different distance than the spacer material 466 in second adjacent recessed regions proximate to a top of the S/D regions. For example, the spacer material 466 in the dimples 437 on a side wall of an S/D region on either side of the layer 432-1 are separated by a distance approximately equal to the thickness 433-1, while the spacer material 466 in the dimples 439 on the side wall of the S/D region on either side of the layer 432-3 are separated by a distance approximately equal to the thickness 433-3.

The method 300 continues with the process 309 of removing the dummy gate. An IC structure 400G of FIG. 4G illustrates an example result of the process 309. As shown in FIG. 4G, removing the dummy gate 446 exposes the material 434 and the semiconductor material 432 at the sidewalls of the fin 440. Removal of the dummy gate 446 may include any suitable etching technique, provided the material of the dummy gate 446 is sufficiently etch-selective with respect to the other materials of the IC structure 400G, in particular, with respect to the semiconductor material 432 and the insulator material 436 surrounding the subfin portion of the fin 440.

The method 300 continues with the process 310 of releasing the nanoribbons in the gate region. An IC structure 400H of FIG. 4H illustrates an example result of the process 310, which shows nanoribbons 404-1-404-4 formed from the layers 432-1-432-4 of semiconductor material. An etch process may be used to remove the second material 434 from the fin 440, starting from the portions of the material 434 that are exposed by the removal of the dummy gate 446. As a result of removing the material 434, a stack 478 of nanoribbons of the semiconductor material 432 is formed. Thus, the nanoribbons of the stack 478 are “released” in that the openings 473 are formed around channel portions of the nanoribbons of the semiconductor material 432.

The method 300 continues with the process 311 of providing gate electrode materials in gate regions and providing S/D contacts. FIGS. 4I and 4J illustrate an example of an IC structure resulting from the process 311. FIG. 4I illustrates the IC structure 400I from the perspective of the x-z plane while FIG. 4J illustrates the IC structure 400J from the perspective of the y-z plane (e.g., a “gate cut”). FIGS. 4I and 4J illustrate an S/D contact material 480 filling the remainder of the openings 454 to form S/D contacts 414-1, 414-2 (referred to herein as simply “S/D contacts 414”), and making an electrical contact to the S/D material 470. In the example illustrated in FIG. 4J, the IC structure 400J further includes an interface material 416 to provide an interface between the S/D material 470 of the S/D regions and the electrically conductive fill material 480 of the S/D contacts 414. The interface material 416 may include/be a metal such as titanium which, once deposited, may intermix with the material of the S/D regions 414, e.g., with silicon, forming a compound (e.g., titanium silicide) that may help reduce contact resistance of the S/D contacts 414. Although FIG. 4J illustrates an example in which the S/D contacts 414 are both on the same side (e.g., a front side) of the IC structure, other examples may include one or more S/D contacts on the opposing side (e.g., a back side) of the IC structure.

FIGS. 4I and 4J further illustrate a gate insulator material 482 that may wrap around the gate regions of the nanoribbons 404-1-404-4 of the stack 478, as well as a gate electrode material 484. The gate insulator material 482 may be the same as or similar to the gate insulator material 212 described above with respect to FIG. 2. Similarly, the gate electrode material 484 may be the same as, or similar to, the gate electrode material 208 described above with respect to FIG. 2. In some embodiments, the gate insulator material 482 may be absent in the IC structures 400I, 400J. The IC structures 400I, 400J and all variations of such structures described herein are examples of the IC structures 100 and 200, described above.

Performing the method 300 may result in features in the final IC structures that are characteristic of the use of the method 300. For example, one such feature is illustrated in the IC structures 400I, 400J shown in FIGS. 4I, 4J, which shows a stack 478 of nanoribbons, where at least one of the nanoribbons has a thickness that is different than the other nanoribbons in the stack 478. For example, referring to FIGS. 4I and 4J, the channel region in the nanoribbon 404-1 that is closest to the subfin 442 and closest to narrower portion of the S/D material 470 has a thickness T1 that is greater than the thickness T4 of the channel region in the nanoribbon 404-4 that is further from the subfin 442 and further from the narrower portion of the S/D material 470. Also as illustrated in FIG. 4J, the channel region in the nanoribbon 404-4 that is closest to the S/D contacts 414-1, 414-2 has a smaller thickness (T4) than the channel region in the nanoribbon 404-1 that is further from the S/D contacts 414-1, 414-2. However, in other embodiments in which one or more S/D contacts are formed on the opposing side of the IC structure (e.g., a back side), the thicker channel region may be closer to the backside S/D contact than a thinner channel region. FIG. 1 also illustrates an example of an IC structure 100 that includes a stack 178 of nanoribbons with different thicknesses that may be formed with the method 300 of FIG. 3.

IC structures including a stack of nanoribbons with different thicknesses as described herein (e.g., as described with reference to FIGS. 1-4J) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures disclosed herein, e.g., the IC structures 100, 200, 400I, and 400J may be included in any suitable electronic component. FIGS. 5-9 illustrate various examples of apparatuses that may include any of the IC structures 100, 200, 400I, and 400J disclosed herein.

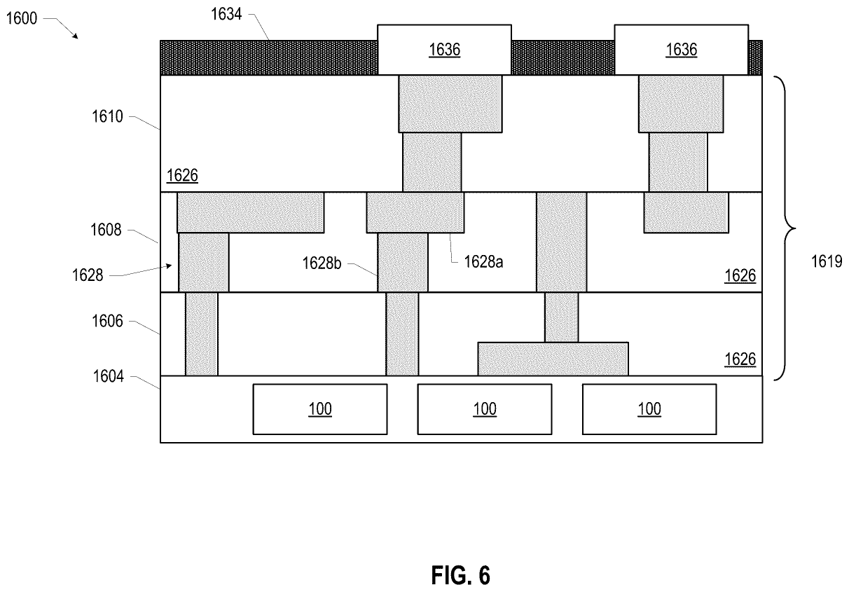

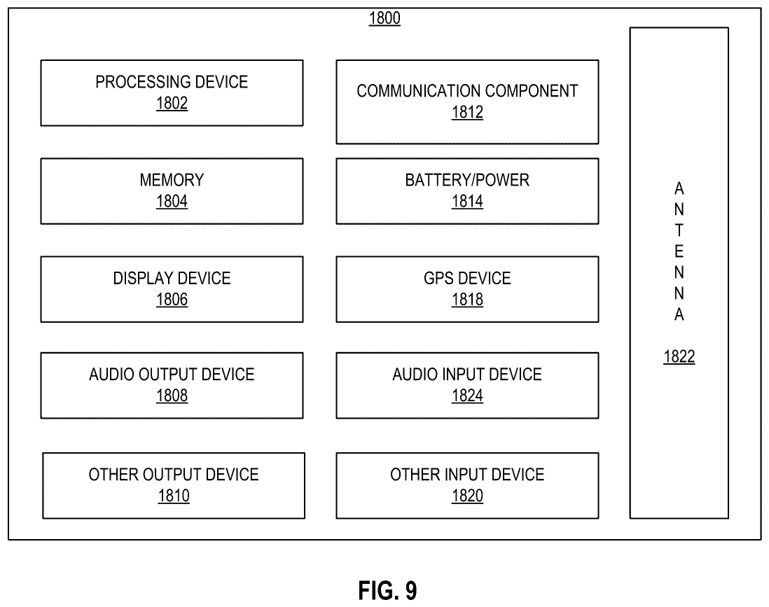

FIG. 5 is a top view of a wafer 1500 and dies 1502 that may include one or more IC structures 100, 200, 400I, and 400J in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures 100, 200, 400I, and 400J (e.g., as discussed below with reference to FIG. 6), one or more transistors (e.g., some of the transistors of the device region 1604 of FIG. 6, discussed below, e.g., nanoribbon-based transistors of the IC structures 100, 200, 400I, and 400J) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 9) or other logic that is configured to store information in the memory devices or execute instructions stored in the memory array.

FIG. 6 is a side, cross-sectional view of an IC device 1600 that may include one or more IC structures in accordance with any of the embodiments disclosed herein (e.g., in accordance with IC structures 100, 200, 400I, and 400J). One or more of the IC devices 1600 may be included in one or more dies 1502 (FIG. 5). The IC device 1600 may include a device region 1604 including one or more IC structures (e.g., one or more of IC structures 100, 200, 400I, and 400J) disclosed herein, or any variations of the IC structures. The device region 1604 may further include electrical contacts to the gates of the transistors included in the device region 1604 and to the S/D materials of the transistors included in the device region 1604 (e.g., to the S/D regions 114 of the IC structures 100).

Electrical signals, such as power and/or input/output (I/O) signals, may be routed to and/or from the devices (e.g., the transistors) of the device region 1604 through one or more interconnect layers disposed on the device region 1604 (illustrated in FIG. 6 as interconnect layers 1606-1610). For example, electrically conductive features of the device region 1604 (e.g., the gate electrode material 184 of the IC structures 100) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 6). Although a particular number of interconnect layers 1606-1610 is depicted in FIG. 6, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support 102 upon which the device region 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 6. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114 of the IC structures 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606-1610. In FIG. 6, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

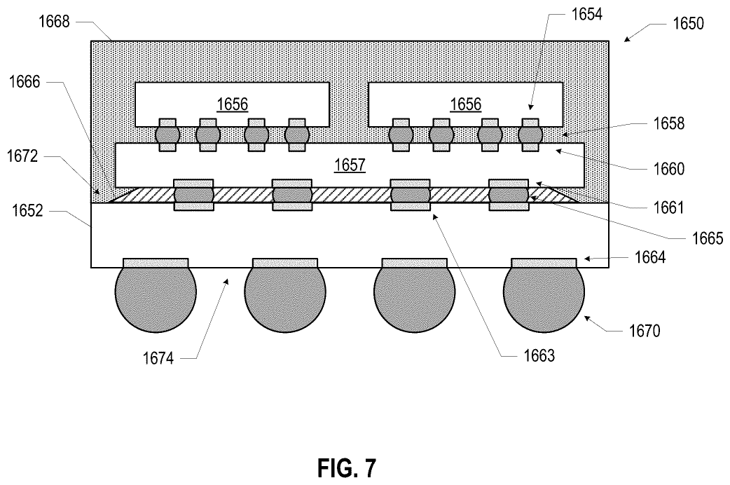

FIG. 7 is a side, cross-sectional view of an example IC package 1650 that may include one or more IC structures 100, 200, 400I, and 400J in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 6.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 7 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 7 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

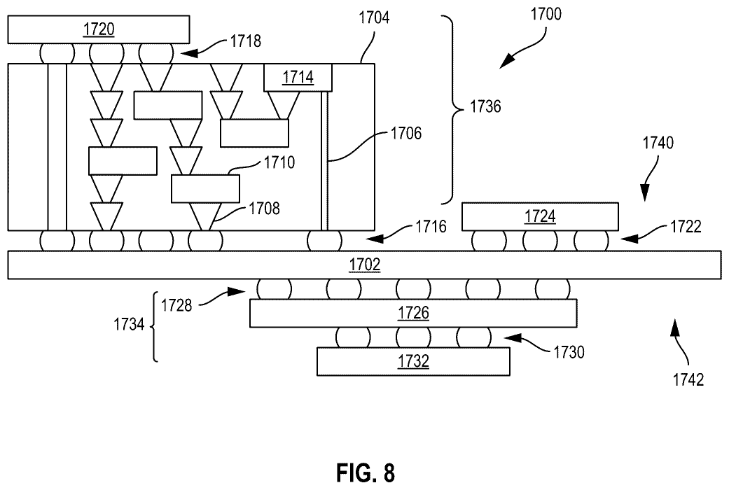

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 7 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 8.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 7 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 7, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 8 is a side, cross-sectional view of an IC device assembly 1700 that may include one or more IC packages or other electronic components (e.g., a die) including one or more IC structures 100, 200, 400I, and 400J in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 7 (e.g., may include one or more IC structures 100, 200, 400I, and 400J).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 8 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 8), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 8, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 5), an IC device (e.g., the IC device 1600 of FIG. 6), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 8, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 8 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 9 is a block diagram of an example electrical device 1800 that may include one or more IC structures 100, 200, 400I, and 400J in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 9 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 9, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure including a support and a stack of nanoribbons stacked above one another over the support. The stack of nanoribbons includes a first nanoribbon with a first channel region and a second nanoribbon with a second channel region, where the first channel region has a first thickness and the second channel region has a second thickness and where the first thickness is different from the second thickness.

Example 2 provides an IC structure according to example 1, where the stack of nanoribbons includes a third nanoribbon with a third channel region, the third channel region has a third thickness, and the third thickness is different than the first thickness and the second thickness.

Example 3 provides an IC structure according to examples 1 or 2, where the first channel region has a first length, the second channel region has a second length, the first length is greater than the second length, and the first thickness is greater than the second thickness.

Example 4 provides an IC structure according to any one of examples 1-3, where a ratio of the first thickness to the first length is substantially equal to a ratio of the second thickness to the second length.

Example 5 provides an IC structure according to any one of examples 1-4, further including a region including a doped semiconductor material, wherein the region is a source region or a drain region, wherein the region includes a first portion (e.g., a bottom of the source/drain region) having a first width, and a second portion (e.g., the top of the source/drain region) having a second width that is greater than the first width, where the first channel region is closer to the first portion than to the second portion, and where the first thickness is larger than the second thickness.

Example 6 provides an IC structure according to any one of examples 1-5, further including a subfin under the stack of nanoribbons, where the first channel region is closer to the subfin than the second channel region, and wherein the first thickness is greater than the second thickness.

Example 7 provides an IC structure according to any one of examples 1-6, where the second channel region is closer to at least one of a source contact or a drain contact than the first channel region.

Example 8 provides an IC structure according to any one of examples 1-7, where a difference between the first thickness and the second thickness is in a range of 5 to 20 percent of the first thickness.

Example 9 provides an IC structure according to any one of examples 1-8, further including a continuous gate electrode material enclosing the first channel region and the second channel region.

Example 10 provides an IC structure including a first nanoribbon including a first channel region of a transistor, wherein the first channel region has a first length and a first thickness, and a second nanoribbon over the first nanoribbon, the second nanoribbon including a second channel region of the transistor, wherein the second channel region has a second length and a second thickness, where the first length is greater than the second length, and first thickness is greater than the second thickness.

Example 11 provides an IC structure according to example 10, further including a third nanoribbon over the second nanoribbon, the third nanoribbon including a third channel region of the transistor, where the third channel region has a third thickness that is smaller than the second thickness.

Example 12 provides an IC structure according to examples 10 or 11, where a ratio of the first thickness to the first length is substantially equal to a ratio of the second thickness to the second length.

Example 13 provides an IC structure according to any one of examples 1-12, further including a region of the transistor that is a source region or a drain region, wherein the region includes a first portion that is closer to the first channel region than to the second channel region and a second portion that is closer to the second channel region than to the first channel region, wherein the first portion has a narrower width than the second portion.

Example 14 provides an IC structure according to any one of examples 1-13, further including a subfin under the first nanoribbon, where the first channel region is closer to the subfin than the second channel region, and wherein the first thickness is greater than the second thickness.

Example 15 provides an IC structure according to any one of examples 1-14, where the second channel region is closer to at least one of a source contact or a drain contact than the first channel region.

Example 16 provides an IC structure according to any one of examples 1-15, where a continuous gate electrode material enclosing the first channel region and the second channel region.

Example 17 provides an IC structure according to any one of examples 1-16, where a difference between the first thickness and the second thickness is in a range of 0.2 nanometer to 1 nanometer.

Example 18 provides an IC structure according to any one of examples 1-17, where the IC structure includes or is a part of a central processing unit.

Example 19 provides an IC structure according to any one of examples 1-18, where the IC structure includes or is a part of a memory device.

Example 20 provides an IC structure according to any one of examples 1-19, where the IC structure includes or is a part of a logic circuit.

Example 21 provides an IC structure according to any one of examples 1-20, where the IC structure includes or is a part of input/output circuitry.

Example 22 provides an IC structure according to any one of examples 1-21, where the IC structure includes or is a part of a field programmable gate array transceiver.

Example 23 provides an IC structure according to any one of examples 1-22, where the IC structure includes or is a part of a field programmable gate array logic.

Example 24 provides an IC structure according to any one of examples 1-23, where the IC structure includes or is a part of a power delivery circuitry.

Example 25 provides an IC package that includes an IC die including an IC structure according to any one of examples 1-24; and a further IC component, coupled to the IC die.

Example 26 provides an IC package according to example 25 where the further IC component includes a package substrate.

Example 27 provides an IC package according to example 25, where the further IC component includes an interposer.

Example 28 provides an IC package according to example 25, where the further IC component includes a further IC die.

Example 29 provides a computing device that includes a carrier substrate and an IC structure coupled to the carrier substrate, where the IC structure is an IC structure according to any one of examples 1-24, or the IC structure is included in the IC package according to any one of examples 25-28.

Example 30 provides a computing device according to example 29, where the computing device is a wearable or handheld computing device.

Example 31 provides a computing device according to examples 29 or 30, where the computing device further includes one or more communication chips.

Example 32 provides a computing device according to any one of examples 29-31, where the computing device further includes an antenna.

Example 33 provides a computing device according to any one of examples 29-32, where the carrier substrate is a motherboard.

Example 34 provides a method of fabricating an IC structure including providing a stack of alternate layers of a semiconductor material and a further material, wherein the stack includes two or more layers of the semiconductor material with different thicknesses, patterning the stack into a fin, and removing portions of the further material to form nanoribbons from the two or more layers of the semiconductor material of the fin, wherein the nanoribbons include a first nanoribbon from a first layer of the semiconductor material and a second nanoribbon from a second layer of the semiconductor material, and wherein the first nanoribbon has a first thickness and the second nanoribbon has a second thickness that is different than the first thickness.

Example 35 provides a method according to example 34, where providing the stack includes providing at least three layers of the semiconductor material with different thicknesses.

Example 36 provides a method according to any one examples 34-35, further including forming a transistor having channel regions in the nanoribbons of the semiconductor material.

Example 37 provides a method according to example 36, where forming the transistor includes forming openings in the stack for a source region and a drain region, where the first layer of the semiconductor material is closer to a bottom of the openings than the second layer of the semiconductor material, and wherein first layer of the semiconductor material is thicker than the second layer of the semiconductor material.

Example 38 provides a method according to example 36, where forming the transistor includes recessing the second material in sidewalls of the openings to form recessed regions (e.g., dimples), and providing an insulator material in the recessed regions, wherein the insulator material in adjacent recessed regions proximate to a bottom of the openings is separated by a different distance than the insulator material in second adjacent recessed regions proximate to a top of the openings.

Example 39 provides a method according to any one of examples 34-38, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a support; and
a stack of nanoribbons stacked above one another over the support, the stack of nanoribbons including a first nanoribbon with a first channel region and a second nanoribbon with a second channel region, wherein the first channel region has a first thickness and the second channel region has a second thickness;
wherein the first thickness is different from the second thickness.

2. The IC structure of claim 1, wherein:
the stack of nanoribbons includes a third nanoribbon with a third channel region,
the third channel region has a third thickness, and
the third thickness is different than the first thickness and the second thickness.

3. The IC structure of claim 1, wherein:
the first channel region has a first length,
the second channel region has a second length,
the first length is greater than the second length, and
the first thickness is greater than the second thickness.

4. The IC structure of claim 3, wherein:
a ratio of the first thickness to the first length is substantially equal to a ratio of the second thickness to the second length.

5. The IC structure of claim 1, further comprising:
a region including a doped semiconductor material, wherein the region is a source region or a drain region,
wherein the region includes:
a first portion having a first width, and
a second portion having a second width that is greater than the first width,
wherein the first channel region is closer to the first portion than to the second portion, and
wherein the first thickness is larger than the second thickness.

6. The IC structure of claim 1, further comprising:
a subfin under the stack of nanoribbons,
wherein the first channel region is closer to the subfin than the second channel region, and
wherein the first thickness is greater than the second thickness.

7. The IC structure of claim 1, wherein:
the second channel region is closer to at least one of a source contact or a drain contact than the first channel region.

8. The IC structure of claim 1, wherein:
a difference between the first thickness and the second thickness is in a range of 5 to 20 percent of the first thickness.

9. The IC structure of claim 1, further comprising:
a continuous gate electrode material enclosing the first channel region and the second channel region.

10. An integrated circuit (IC) structure, comprising:
a first nanoribbon including a first channel region of a transistor, wherein the first channel region has a first length and a first thickness; and
a second nanoribbon over the first nanoribbon, the second nanoribbon including a second channel region of the transistor, wherein the second channel region has a second length and a second thickness,
wherein the first length is greater than the second length, and first thickness is greater than the second thickness.

11. The IC structure of claim 10, further comprising:
a third nanoribbon over the second nanoribbon, the third nanoribbon including a third channel region of the transistor, wherein the third channel region has a third thickness that is smaller than the second thickness.

12. The IC structure of claim 10, wherein:
a ratio of the first thickness to the first length is substantially equal to a ratio of the second thickness to the second length.

13. The IC structure of claim 10, further comprising:
a region of the transistor that is a source region or a drain region,
wherein the region includes:
a first portion that is closer to the first channel region than to the second channel region and a second portion that is closer to the second channel region than to the first channel region,
wherein the first portion has a narrower width than the second portion.

14. The IC structure of claim 10, further comprising:
a subfin under the first nanoribbon;
wherein the first channel region is closer to the subfin than the second channel region, and wherein the first thickness is greater than the second thickness.

15. The IC structure of claim 10, wherein:
the second channel region is closer to at least one of a source contact or a drain contact than the first channel region.

16. The IC structure of claim 10, further comprising:
a continuous gate electrode material enclosing the first channel region and the second channel region.

17. The IC structure of claim 10, wherein:
a difference between the first thickness and the second thickness is in a range of 0.2 nanometer to 1 nanometer.

18. A method of fabricating an integrated circuit (IC) structure, the method comprising:
providing a stack of alternate layers of a semiconductor material and a further material, wherein the stack includes two or more layers of the semiconductor material with different thicknesses;
patterning the stack into a fin; and
removing portions of the further material to form nanoribbons from the two or more layers of the semiconductor material of the fin, wherein the nanoribbons include a first nanoribbon from a first layer of the semiconductor material and a second nanoribbon from a second layer of the semiconductor material, and wherein the first nanoribbon has a first thickness and the second nanoribbon has a second thickness that is different than the first thickness.

19. The method of claim 18, wherein providing the stack includes providing at least three layers of the semiconductor material with different thicknesses.

20. The method of claim 18, further comprising:
forming a transistor having channel regions in the nanoribbons of the semiconductor material.
